(19) United States
(12) Patent Application Publication
(10) Pub. No.: US 2026/0203465 A1
(43) Pub. Date: Jul. 16, 2026

(54) FPGA-ACCELERATED DPU CREATION

(71) Applicant: MangoBoost, Inc., Bellevue, WA (US)

(72) Inventors: Heetaek JEONG, Bellevue, WA (US); Wonsik LEE, Seoul (KR); Dongup KWON, Seoul (KR); Eriko NURVITADHI, Bellevue, WA (US)

(21) Appl. No.: 19/372,982

(22) Filed: Oct. 29, 2025

Related U.S. Application Data
(60) Provisional application No. 63/744,752, filed on Jan. 13, 2025.

(51) Int. Cl. G06F 30/20; G06F 11/3668

(52) U.S. Cl. CPC G06F 30/20; G06F 11/3696

(57) ABSTRACT

A DPU creation system is described herein. The DPU creation system may receive an indication of one or more data processing unit (DPU) design specifications. The DPU creation system selects one or more protocols and one or more hardware modules for a DPU based on the DPU design specifications. The DPU creation system generates a simulated representation of the DPU by composing the one or more protocols and the one or more hardware modules. The DPU creation system tests the simulated representation of the DPU and determine whether to modify one or more aspects of the DPU based on test result data and design specifications. The DPU creation system may cause an aspect of the simulated representation of the DPU to be modified based on the determination. The DPU creation system may cause a hardware implementation of the DPU to be created based on the simulated representation of the DPU.

### BACKGROUND

### Technical Field

This application is related to specialized Data Processing Units (DPUs), which are used as specialized accelerators to offload and accelerate data-centric operations.

### BRIEF SUMMARY

Designing DPUs to efficiently accelerate these tasks remains challenging for conventional systems. This is due to (1) the highly diverse range of services, (2) the high performance requirements they impose, (3) the need for seamless integration with existing datacenter infrastructures, and (4) the urgency for fast time-to-market to meet rapidly changing workload demands. In order to address the issues faced by conventional DPU design systems, various embodiments of a DPU creation system as described herein are able to mitigate these issues in conventional systems by designing, testing, and optimizing DPUs based on the protocols and hardware modules incorporated in the DPU.

In some embodiments, a DPU creation system comprises at least one processor; and at least one memory coupled to the at least one processor, the memory having computer-executable instructions stored thereon that, when executed by the at least one processor, cause the system to: receive an indication of one or more data processing unit (DPU) design specifications; select one or more protocols for a DPU based on the one or more DPU design specifications; select one or more hardware modules for the DPU based on the one or more protocols; generate a simulated representation of the DPU by composing the one or more protocols and the one or more hardware modules; test the simulated representation of the DPU to obtain test result data; determine whether to modify one or more aspects of the DPU based on the test result data and the one or more DPU design specifications; based on a determination that one or more aspects of the DPU are to be modified, modify the one or more aspects of the simulated representation of the DPU; and cause a hardware implementation of a DPU to be created based on the simulated representation of the DPU.

To generate the simulated representation of the DPU, the DPU creation system may: generate a graph of the one or more protocols and one or more interfaces between the protocols, the one or more interfaces being associated with the one or more hardware modules, wherein the one or more protocols are represented by nodes and the one or more interfaces are represented by edges.

To select the one or more protocols, the DPU creation system may: access data indicating a function of each protocol of a plurality of protocols; access data indicating one or more data interactions of each protocol of the plurality of protocols with one or more other protocols of the plurality of protocols; and select the one or more protocols based on the data indicating the function of each protocol of the plurality of protocols, the data indicating one or more data interactions of each protocol of the plurality of protocols with one or more other protocols of the plurality of protocols, and the DPU design specifications. The DPU creation system may also combine at least two protocols based on a function of each of the at least two protocols and the DPU design specifications.

To select one or more hardware modules for the DPU, the DPU creation system may: identify a plurality of hardware modules based on the DPU design specifications; access data indicating compatibility between each of the plurality of hardware modules and each of the one or more protocols; and select the one or more hardware modules based on the compatibility of each of the plurality of hardware modules and each of the one or more protocols.

To generate a simulated representation of the DPU, the DPU creation system may: identify a resource cost for each hardware module of the one or more hardware modules; identify a resource cost for each protocol of the one or more protocols; and select a location within the DPU for each hardware module of the one or more hardware modules based on the resource cost for each hardware module and the resource cost for each protocol.

To test the simulated representation of the DPU, the DPU creation system may: access one or more pre-determined test cases for the one or more protocols and the one or more hardware modules; and test the simulated representation of the DPU based on the one or more pre-determined test cases.

To test the simulated representation of the DPU, the DPU creation system may: identify one or more bugs encountered during the test of the simulated representation of the DPU, the one or more bugs affecting functionality of at least one protocol of the one or more protocols or functionality of at least one hardware module of the one or more hardware modules; identify a solution for the one or more bugs encountered during the test of the simulated representation of the DPU; and generate a test case for the at least one protocol or the at least one hardware module based on the one or more bugs and the solution.

To test the simulated representation of the DPU, the DPU creation system may: determine whether a resource utilization of at least one protocol of the one or more protocols or at least one hardware module of the one or more hardware modules has exceeded a threshold amount based on a first test of the simulated representation of the DPU; select the at least one protocol or the at least one hardware module of the one or more hardware modules based on a determination that the resource utilization of the at least one protocol or the at least one hardware module exceeded the threshold amount; implement monitoring code to the at least one protocol or the at least one hardware module in the simulated representation of the DPU, the monitoring code being configured to generate monitoring statistics during testing for the at least one protocol or the at least one hardware module; perform a second test of the simulated representation of the DPU; and receive monitoring statistics generated during the second test of the simulated representation of the DPU. The DPU creation system may determine whether a resource utilization of the at least one protocol or the at least one hardware modules has exceeded a threshold amount by identifying one or more bugs encountered during the test of the simulated representation of the DPU, the one or more bugs affecting functionality of at least one protocol of the one or more protocols or functionality of at least one hardware module of the one or more hardware modules. The DPU creation system may determine whether a resource utilization of the at least one protocol or the at least one hardware modules has exceeded a threshold amount, by identifying one or more optimization directives included in the one or more DPU design specifications.

A method of generating a DPU design may include: receiving an indication of one or more data processing unit (DPU) design specifications; selecting one or more protocols for a DPU based on the one or more DPU design specifications; selecting one or more hardware modules for the DPU based on the one or more protocols; generating a simulated representation of the DPU by composing the one or more protocols and the one or more hardware modules; testing the simulated representation of the DPU to obtain test result data; determining whether to modify one or more aspects of the DPU based on the test result data and the one or more DPU design specifications; based on a determination that one or more aspects of the DPU are to be modified, modifying the one or more aspects of the simulated representation of the DPU; and causing a hardware implementation of a DPU to be created based on the simulated representation of the DPU.

One or more instances of non-transitory computer-readable media including processor-executable instructions may be configured to cause a processor to perform a method comprising: receiving an indication of one or more data processing unit (DPU) design specifications; selecting one or more protocols for a DPU based on the one or more DPU design specifications; selecting one or more hardware modules for the DPU based on the one or more protocols; generating a simulated representation of the DPU by composing the one or more protocols and the one or more hardware modules; testing the simulated representation of the DPU to obtain test result data;

determining whether to modify one or more aspects of the DPU based on the test result data and the one or more DPU design specifications; based on a determination that one or more aspects of the DPU are to be modified, modifying the one or more aspects of the simulated representation of the DPU; and causing a hardware implementation of a DPU to be created based on the simulated representation of the DPU.

### BRIEF DESCRIPTION OF THE SEVERAL VIEWS OF THE DRAWINGS

FIG. 1 is a block diagram of a DPU creation system, according to various embodiments described herein.

FIG. 2 is a flow diagram of a sample process to create a DPU, according to various embodiments described herein.

FIG. 3 is a table diagram of a sample protocol table, according to various embodiments described herein.

FIG. 4 is a graph diagram of a sample simulated DPU representation, according to various embodiments described herein.

FIG. 5 is a flow diagram of a sample DPU testing process, according to various embodiments described herein.

FIG. 6 is a flow diagram of a sample process to inject monitoring code into a simulated representation of a DPU, according to various embodiments described herein.

FIG. 7 is a schematic block diagram of an exemplary computing device that can be used to implement embodiments of the present disclosure.

FIG. 8 illustrates an exemplary system architecture in which embodiments of the disclosure may be implemented.

### DETAILED DESCRIPTION

Modern datacenters face significant challenges in managing data processing tasks as the demands driven by emerging AI and Big Data workloads continue to grow rapidly. These workloads require immense computational resources to handle tasks such as storage management and network processing. This escalating demand places tremendous strain on general-purpose processors, leading to inefficiencies in performance and scalability. To mitigate these inefficiencies, Data Processing Units (“DPUs”) have been introduced as specialized accelerators tailored to offload and accelerate data-centric operations.

However, designing DPUs to efficiently accelerate these tasks remains challenging for conventional systems. This is due to (1) the highly diverse range of services, (2) the high performance requirements they impose, (3) the need for seamless integration with existing datacenter infrastructures, and (4) the urgency for fast time-to-market to meet rapidly changing workload demands.

First, conventional systems cannot design DPUs to support a wide range of modern datacenter workloads. These workloads now span multiple domains, including networking, storage, virtualization, PCIe communication, and internal data processing, which require data centers to support tasks across multiple domains for a single workload. This integration leads to higher costs and greater complexity in managing these workloads. For example, as workloads scale and demand multi-node communication, NVMe over Fabrics (NVMe-oF) has emerged to integrate storage and networking, enabling high-speed data transfer across distributed environments. In such cases, data centers must support both storage and networking features, resulting in even higher overhead compared to using local storage.

Second, conventional systems cannot design DPUs to efficiently accelerate data processing tasks to meet the tight performance requirements of workloads. For instance, fabric technologies, such as PCIe and Ethernet, are advancing rapidly, with Ethernet bandwidth reaching up to 800 Gbps. However, despite improvements in fabric performance, actual workload performance often fails to meet the desired speeds, because software management systems unrelated to the applications impose significant overheads. In some systems, nearly 60% of CPU cores are utilized for NVMe virtualization, preventing them from being used for meaningful user applications. Thus, conventional systems are unable to design DPUs that can reduce the high amount of CPU usage of the server that uses the DPU. Virtualization techniques further amplify the computational demands by introducing overheads in tasks like packet processing, hypervisor management, and storage access coordination. The integration of software-defined networking (SDN) and network overlays like Open vSwitch (OVS) adds another layer of complexity.

Third, conventional systems cannot design DPUs to be easy to use and deploy while ensuring compatibility with existing systems. Datacenters rely on large-scale legacy infrastructures, making compatibility with existing systems critical. To maintain compatibility, for example, datacenters adopt standard protocols and abstraction layers (such as NVMe and Virtio-net) to simplify IT management and improve scalability. They also ensure the smooth operation of legacy software by minimizing disruptions when integrating new technologies. Accordingly, conventionally designed DPUs do not ensure compatibility with existing systems to enable seamless and easy-to-deploy integration.

Fourth, conventional systems cannot design DPUs to meet fast time-to-market requirements in order to adapt to rapidly changing market trends. Neither ASICs nor general-purpose cores effectively address these challenges. While ASICs offer high performance, they lack the flexibility to adapt to rapidly changing workloads, and their lengthy and costly design and production cycles make them unsuitable for tasks requiring frequent updates or workload-specific adjustments. General-purpose cores are more flexible but struggle to meet the high-performance demands of data-intensive workloads.

FPGAs have emerged as a compelling platform for implementing DPUs and offer flexibility and reconfigurability, making them particularly well-suited for adapting to rapidly changing workloads while delivering high performance through customized hardware acceleration. However, FPGAs also face inherent challenges, such as increased complexity in design and optimization, due to their architecture. For example, their pre-fabricated logic blocks and fixed routing resources can limit design flexibility and make optimization more difficult.

Various embodiments of a DPU creation system as described herein are able to mitigate these issues in conventional systems by designing, testing, and optimizing DPUs based on the protocols and hardware modules incorporated in the DPU. For instance, the DPUs designed by the DPU creation system are able to efficiently offload and accelerate the data storage and networking tasks. Additionally, the DPUs designed by the DPU creation system are able to manage diverse and complex workloads across a wide range of domains. DPUs designed by the DPU creation system are also able to ensure compatibility with existing systems to enable seamless and easy-to-deploy integration. Furthermore, DPUs designed by the DPU creation system are able to meet the high-performance demands of data-intensive workloads better than general-purpose cores. The DPU creation system is also able to design DPUs with FPGAs that are more flexible and optimizable than conventional FPGAs.

The DPU creation system designs DPUs to deliver fast, seamless, and versatile solutions for a wide range of data processing tasks. In some embodiments, DPUs created based on the designs generated by the DPU creation system accelerate critical datacenter operations entirely on FPGA hardware, ensuring high performance. In some embodiments, the DPU creation system includes a development framework that employs a novel composable design methodology. In some embodiments, the development framework includes a library module, an optimizer module, a verification module, a compiler module, other modules, or some combination thereof.

A DPU is a specialized processor designed to offload and accelerate data processing tasks away from general-purpose CPUs. In some embodiments, by incorporating hardware accelerators and embedded CPU cores, DPUs designed by the DPU creation system reduce the overhead associated with data movement and protocol handling. This not only frees up CPU cycles for more complex operations but also supports high-throughput, low-latency, data processing. ASIC-based DPUs offer high performance and energy efficiency with fixed hardware functions, while FPGA-based DPUs trade the efficiency for reconfigurability and adaptability to evolving technologies and trends in datacenter.

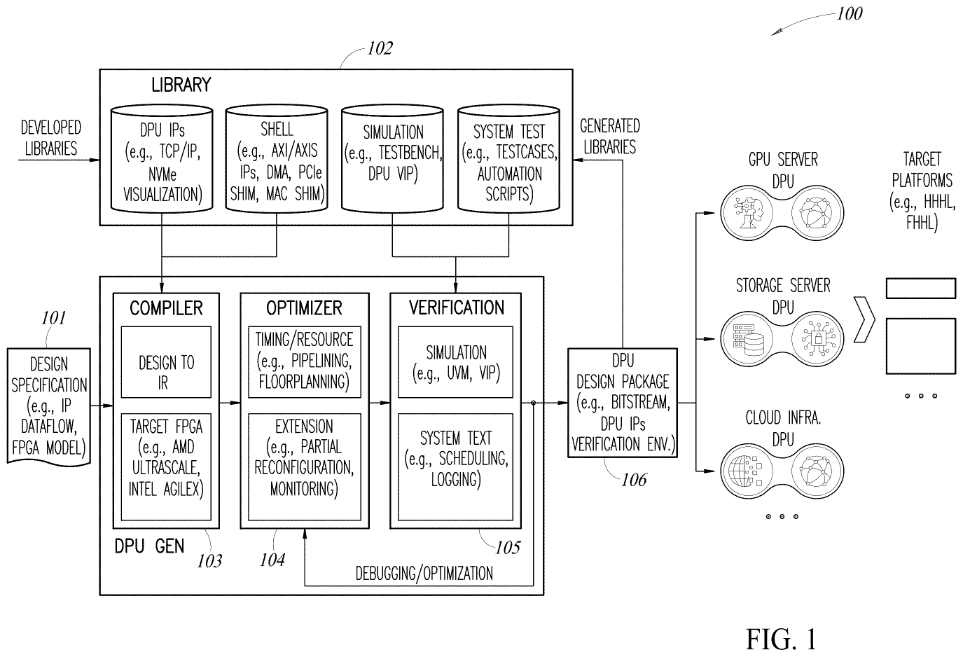

FIG. 1 is a block diagram of a DPU creation system 100, according to various embodiments described herein. The DPU creation system 100 includes a library module 102, a compiler module 103, an optimizer module 104, and a verification module 105. The DPU creation system 100 receives a design specification 101 as input and outputs a design package 106. The design package 106 may be used to create a DPU of one or more types, such as a GPU server DPU, a storage server DPU, a cloud infrastructure DPU, other types of DPU, etc. The DPU created by using the design package 106 may be implemented on one or more hardware platforms, such as HHHL, FHHL, etc. Each one of the modules 102-105 may be implemented via hardware, software, machine learning, or some combination thereof.

The design specification 101 may include: an indication of one or more protocols, an indication of one or more parameters for one or more protocols, an indication of the flow of data between the one or more protocols, an indication of one or more target FPGA platform, an indication of one or more optimization directives, other information useful for designing a DPU, or some combination thereof. In some embodiments, the DPU creation system 100 receives the design specification 101 via user input. In some embodiments, in response to receiving the design specification 101, the DPU creation system 100 provides the design specification to the compiler module 103.

The library module 102 includes data indicating one or more protocols, one or more shells, simulation data, system test data, other data associated with the creation of DPUs, or some combination thereof. In some embodiments, the data indicating one or more protocols includes one or more libraries for the one or more protocols. The one or more shells manage communication and interactions between one or more protocols and one or more interfaces. In some embodiments, the data indicating one more shells includes data regarding the protocols and interfaces managed by the one or more shells. In some embodiments, by using the one or more shells to manage interactions between the protocols and the external interface of the DPU, the DPU creation system 100 is able to reduce redundancy and simplify the design of individual modules. In some embodiments, the DPU creation system uses a unified shell that facilitates communication with external interfaces and modularized protocols to generate a simulated representation of the DPU. For instance, the protocols may be combined in different ways based on their boundaries, and the unified shell may be used to facilitate communication between protocols and external interfaces. By operating in this manner, the DPU creation system is able to compose and reuse libraries based on the design specification 101, and also to design DPUs in a way that ensures the DPUs can be easily integrated and deployed into existing systems.

In some embodiments, the data indicating one or more protocols includes a definition of one or more boundaries of the protocols. In such embodiments, the DPU creation system 100 uses the boundaries of the one or more protocols to improve the modularity and reusability of the protocols. In some embodiments, the simulation data includes data regarding bugs, bug fixes, other simulation data associated with the simulation of a DPU, or some combination thereof. In some embodiments, the system test data includes data associated with the testing a DPU, such as test cases, test scripts, test-benches, testing directives, test data from simulated DPUs, other types of testing data, or some combination thereof.

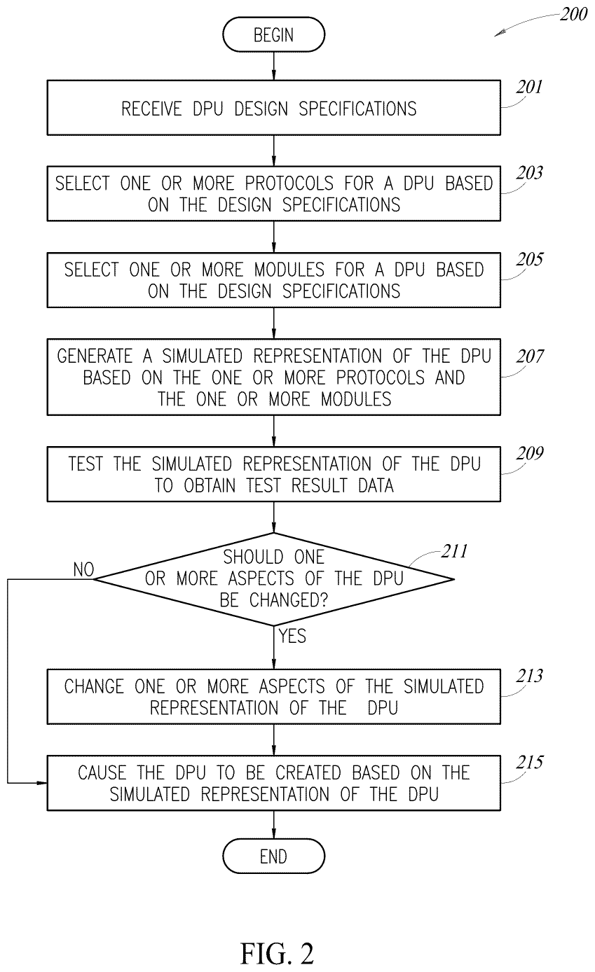

The compiler module 103 generates a simulated representation of the DPU based on the received design specification. In some embodiments, the compiler module 103 generates the simulated representation by using one or more of the processes 200, 500, and 600, described below in connection with FIGS. 2, 5, and 6, respectively. In some embodiments, the simulated representation of the DPU is a graph representing the DPU, where nodes of the graph store key information about protocols, such as interface type (e.g., AXI-MM, AXI-Stream), FPGA resource utilization, etc., while edges of the graph represent the flow of data between protocols. In some embodiments, the DPU creation system 100 provides one or more user interfaces for manipulating or changing one or more aspects of the simulated representation of the DPU, such as changing or adding nodes or edges, moving nodes or edges, etc. In some embodiments, the DPU creation system 100 configures the simulated DPU representation based on one or more target FPGA platforms indicated by the design specifications 101. In some embodiments, the DPU creation system 100 selects one or more hardware modules, one or more protocols, or some combination thereof, for generating the simulated representation of the DPU based on an estimated resource utilization of the one or more hardware modules, the one or more protocols, or a combination thereof, and the design specifications 101. In such embodiments, the resource utilization of the one or more hardware modules, one or more protocols, or a combination thereof, may be used to select a location for each of the hardware modules, protocols, or a combination thereof, within the DPU.

The optimizer module 104 modifies a representation of the DPU generated by the compiler module 103 based on one or more optimization directives included in the design specification 101. In some embodiments, optimizer module 104 determines whether optimizations are to be added to the simulated representation of the graph based on one or more optimization directives included in the design specifications 101. For example, optimizer module 104 may include monitoring circuitry for one or more aspects of the simulated DPU in the simulated representation of the DPU. In such an example, the monitoring circuitry may collect statistics regarding the performance of the DPU during testing, such as utilization or resources. In another example, the optimizer module 104 designates one or more non-shell components as partial reconfiguration regions to allow the protocols included in the DPU to be reconfigured after the DPU is deployed. In such an example, designating the reconfiguration regions allows the protocols of a DPU to be reconfigured after the DPU is created and deployed, which may enhance flexibility and significantly reduce compilation time for iteration or modification of non-shell components.

The verification module 105 performs one or more tests, simulations, or a combination thereof, on the simulated representation of the DPU. In some embodiments, the verification module 105 performs the one or more tests, simulations, or a combination thereof, based on simulation data, test data, or a combination thereof, received from the library module 102. In some embodiments, the verification module 105 provides data regarding the results of the simulations, tests, or a combination thereof, to the library module 102 to improve the testing of other DPUs created by the DPU creation system 100.

In some embodiments, the DPU creation system is able to perform tasks of the compiler module 103, optimizer module 104, verification module 105, other modules, or some combination thereof, automatically. In such embodiments, the DPU creation system may automatically correct timing closure issues, resource optimization issues, design complexity issues, other issues, or some combination thereof. In some embodiments, the DPU creation system corrects these issues based on a simulated representation of the DPU.

The design package 106 includes an indication of the DPU created by the DPU creation system 100. In some embodiments, the design package enables the design to be deployed on appropriate platforms that are compatible with the target system. In such embodiments, this capability ensures seamless integration into diverse datacenter infrastructures while maintaining flexibility across varying hardware configurations. In some embodiments, the design package 106 is used to create one or more types of DPUs based on the simulated representation of the DPU, such as Graphics Processing Unit server DPUs, Storage Server DPUs, Cloud Infrastructure DPUs, Artificial Intelligence DPUs, other types of DPUs, or some combination thereof. In such embodiments, the DPUs are caused to be constructed on one or more target platforms indicated by the design specifications 101, such as HHHL, FHHL, other platforms, or some combination thereof. In some embodiments, the DPU creation system 100 causes data indicating one or more libraries generated as part of creating the design package 106 to be provided to the library module 102 to aid in the creation of other DPUs.

FIG. 2 is a flow diagram of a sample process 200 to create a DPU, according to various embodiments described herein. While the process 200 is described as being performed by a DPU creation system 100, embodiments are not so limited, and the process 200 may be performed by any one or more computing devices or systems with access to at least one of the modules described above in connection with the DPU creation system 100.

The process 200 begins at act 201, where a DPU creation system receives DPU design specifications, such as the design specifications 101 described above in connection with FIG. 1.

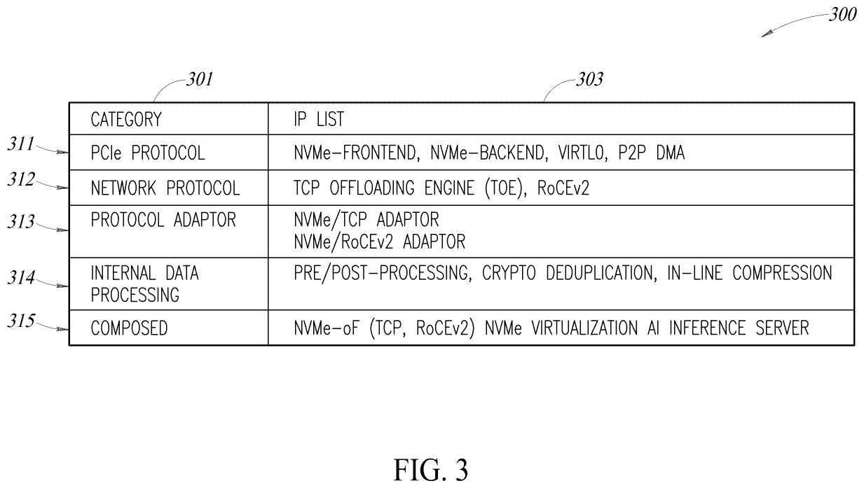

The process 200 proceeds to act 203, where the DPU creation system selects one or more protocols for a DPU based on the design specifications. In some embodiments the selected one or more protocols include at least one protocol that is a combination of aspects of two or more protocols. In such embodiments, the DPU creation system 100 may combine aspects of the two or more protocols based on the design specifications. The combination of aspects of two or more protocols is described below in connection with FIG. 3. In some embodiments, at least one protocol of the one or more protocols is selected via input, such as user input, an indication of the at least one protocol in the design specifications, etc.

In some embodiments, if at least one protocol is not included in a library module of the DPU creation system 100, the DPU creation system 100 obtains an indication of the at least one protocol, such as via user input, retrieving the protocol from a datastore of protocols, or some combination thereof. In some embodiments, the DPU creation system 100 receives input indicating an update to one or more protocols. In such embodiments, the updated protocol is included in the library module of the DPU creation system 100 and made available for use in designing other DPUs.

The process 200 proceeds to act 205, where the DPU creation system selects one or more hardware modules for a DPU based on the design specification. In some embodiments, the one or more hardware modules are selected based on the protocols selected for the DPU, the flow of data between the protocols, the target FPGA platform, other data included in the design specifications, or some combination thereof. In some embodiments, as part of selecting the one or more hardware modules, the DPU creation system 100 selects one or more shells based on the flow of data between the protocols, the one or more protocols, the FPGA platform, other data included in the design specifications, or some combination thereof.

The process 200 proceeds to act 207, where the DPU creation system generates a simulated representation of the DPU based on the one or more protocols and the one or more modules. In some embodiments, the simulated representation of the DPU includes additional aspects related to optimization directives included in the design specifications, such as monitoring code, partial reconfiguration regions, other optimization features, or some combination thereof. In some embodiments, the DPU creation system determines a location for each protocol and hardware module included in the DPU based on the resource utilization of the protocol or hardware module.

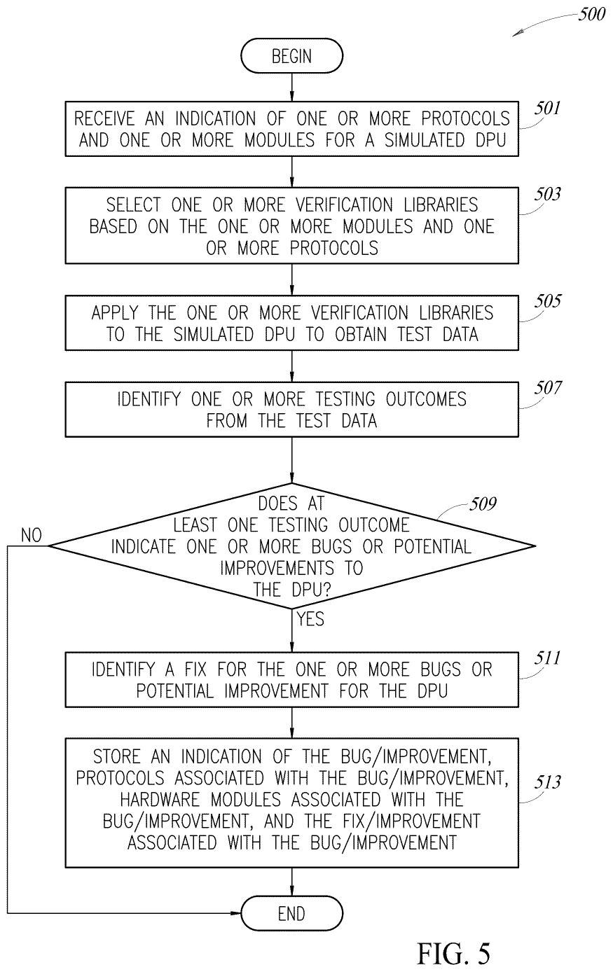

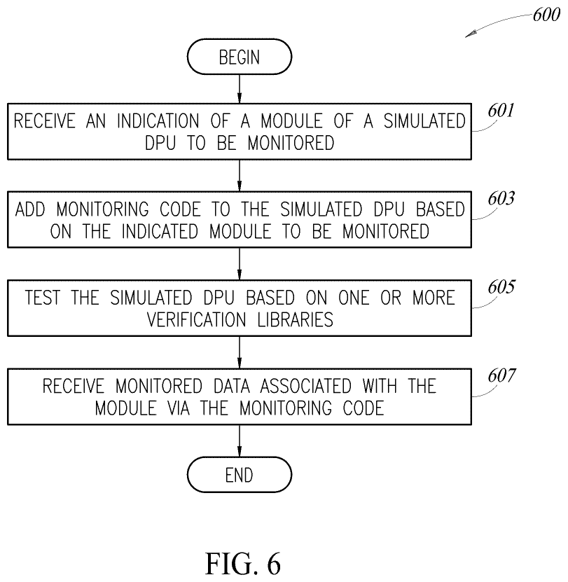

The process 200 proceeds to act 209, where the DPU creation system test the simulated representation of the DPU to obtain test result data. In some embodiments, after the DPU creation system 100 generates a simulated representation of the DPU, the DPU creation system 100 generates a verification, or testing, environment for the DPU. In some embodiments, testing the DPU includes one or more iterative cycles of debugging, optimization, and verification to ensure the reliability and performance of the design of the DPU. In some embodiments, the DPU creation system 100 performs one or more of the processes 500 and 600, described below in connection with FIGS. 5 and 6 respectively, to test the simulated representation of the DPU.

The process 200 proceeds to act 211 where the DPU creation system determines whether one or more aspects of the DPU should be changed based on the test result data, the design specifications, or some combination thereof.

If one or more aspects of the DPU should be changed, the process 200 proceeds to act 213, otherwise, the process 200 proceeds to act 215.

At act 213, the DPU creation system changes one or more aspects of the simulated representation of the DPU. In some embodiments, the DPU creation system 100 changes one or more aspects of the DPU by dividing the simulated representation of the DPU into one or more partitions. In some embodiments, the one or more partitions are selected based on a minimization of the number of signals crossing the partition boundaries.

In some embodiments, the DPU creation system 100 changes one or more aspects of the DPU by identifying one or more timing-critical connections (or interfaces) within the design and automatically applying pipelining with n-pipeline stages to enhance timing. In some such embodiments, the number of pipeline stages (n) is automatically determined based on how critical the connection is.

In some embodiments, the DPU creation system 100 changes one or more aspects of the simulated representation of the DPU by changing one or more aspects designated as partial reconfiguration regions. In some embodiments, changing one or more aspects designated as partial reconfiguration regions includes allocating the partial reconfiguration regions to different regions in the simulated representation of the DPU. In such embodiments, the DPU creation system 100 is able to better optimize and manage the resources in smaller problems for each region and treat all non-shell components included in a reconfiguration region as a single reconfigurable module (the default setting) or divide them into smaller reconfigurable modules for faster compilation cycles and dynamic reconfiguration of the protocol when the DPU is deployed. In such embodiments, the DPU creation system 100 is able to achieve faster compilation times than conventional systems by isolating changes to the modified region while seamlessly linking it to static parts of the design.

In some embodiments, by identifying one or more regions of the DPU as reconfigurable regions, the DPU creation system 100 is able to deploy upgraded versions or bug fixes to those regions during operation, while the rest of the DPU continues to function uninterrupted. In such embodiments, the DPU creation system 100 may integrate a processing system into the hardware of the DPU. Thus, in such embodiments, the DPU creation system 100 may cause a modified partial bitstream to be transmitted within the DPU via interfaces like PCIe or Ethernet.

The process 200 proceeds to act 215, the DPU creation system 100 causes the DPU to be created based on the simulated representation of the DPU. In some embodiments, the DPU creation system 100 causes the DPU to be created by transmitting a design package, such as the design package 106, to one or more entities that create physical versions of a DPU. In some embodiments, the DPU creation system 100 determines whether any protocols included in the design package are not already stored in a library module of the DPU creation system 100. In such embodiments, the DPU creation system 100 causes such protocols to be included in the library module. In some embodiments, the DPU creation system 100 causes test data associated with testing and simulating the DPU for which the design package was created to be stored in the library.

After act 215, the process 200 ends.

FIG. 3 is a table diagram of a sample protocol table 300, according to various embodiments described herein. The protocol table 300 includes a category of protocol column 301 and a list of protocols column 303. The protocol table 300 may be included in a library module, such as the library module 102. While the protocol table 300 is depicted in FIG. 3 as being in human-readable form, embodiments are not so limited, and the protocol table 300 may include data that is not in human-readable form. Additionally, in some implementations, the protocol table 300 may include additional data or less data (e.g., additional protocols, additional data regarding protocols, etc.), additional columns, additional rows, etc., than is depicted in the protocol table 300.

The category protocol column 301 includes data indicating a category of protocols listed in the protocol table 300. The categories of protocols may include any protocols used by a DPU, such as network protocols, PCIe protocols, adaptor protocols, internal data processing protocols, composed protocols, and other types of protocols. Composed protocols are protocols that are combinations of aspects of one or more protocols (such as a protocols that include aspects of a PCIe protocol and a network protocol; an internal data processing protocol, a network protocol, and an adaptor protocol; etc.). The PCIe protocol and network protocols support specific protocols implemented over basic PCIe transactions or ethernet networks. The adaptor protocols operate on top of specific protocol layers while enabling protocol-agnostic data processing. The internal data processing protocols handle other data processing within the protocol-agnostic environment established by the adaptor protocols. In some embodiments, an internal data processing protocol may be inserted between two other protocols to transform data flowing from one protocol to the other. For example, the internal data processing protocols can transform data formats or perform encryption and decryption tasks in the middle of the data flow.

The list of protocols column 303 includes data indicating protocols that belong to a category of protocols. For example, the PCIe protocols may include NVMe-frontend protocols, NVMe-backend protocols, etc. As another example, the protocol adaptors may include NVMe to TCP adaptor protocols, NVMe to RoCEv2 adaptor protocols, etc. In some embodiments, the data indicating protocols includes a name of the protocol and one or more libraries associated with the protocol.

In some embodiments, the protocols included in the protocol table 300 include a modular structure. In such embodiments, the DPU creation system 100 may identify one or more “boundaries” of each protocol included in the library. In some embodiments, a boundary of a protocol indicates a complete function performed by the protocol, such as to accelerate one or more tasks. For example, internal data processing protocols, such as pre/post-processing and in-line compression, are each standalone functions designed to perform specific operations independently of external protocols. In some embodiments, a boundary of a protocol indicates when a protocol interacts with an external interface protocol, such as a PCIe protocol or network protocol.

The boundaries of each protocol are usable to generate one or more of the composed protocols based on aspects of one or more different protocols. For example, the NVMe virtualization protocol is composed of two modules: NVMe-frontend module for communication with the host CPU and NVMe-backend module for interaction with the NVMe device. As another example, a NVMe/TCP initiator, for accessing remote storage, the NVMe-frontend protocol and the TCP offloading Engine (TOE) protocol are combined. In this example, to enable NVMe/TCP acceleration an adapter protocol, referred to as the NVMe/TCP adaptor—which converts protocols between NVMe and TCP—is combined with the NVMe/TCP initiator. Thus, in this example, a NVMe/TCP target acceleration IP is created by combining the NVMe-backend IP, the NVMe/TCP adaptor IP, and the TOE IP.

In some embodiments, one or more of the protocols are designed to eliminate redundant data copies, unnecessary memory access during protocol, etc., when protocols are combined to create composed protocols. For example, the NVMe/TCP protocol utilizes a separate data buffer for TCP and NVMe, when it runs on a CPU. However, the composed version of the protocol replaces the data buffer in NVMe/TCP adaptor IP with a data stream-based interface.

In some embodiments, the DPU creation system 100 causes the composed protocols to be generated based on the boundaries of the protocols being combined. In such embodiments, the DPU creation system 100 may cause the composed protocols to be generated by indicating the protocols to be combined and the boundaries of those protocols to a user, a system configured to automatically combine protocols, or some combination thereof.

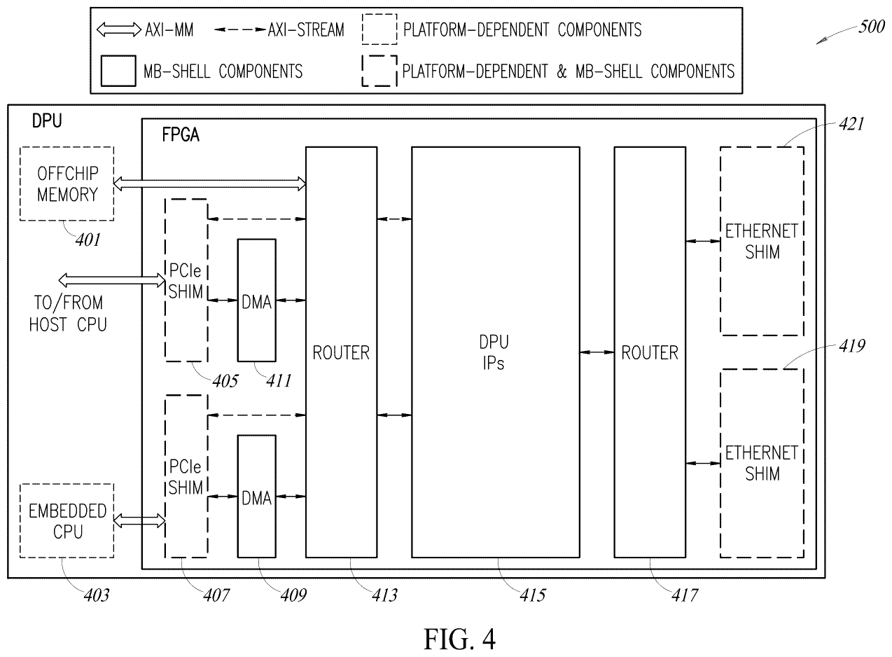

FIG. 4 is a graph diagram of a sample simulated DPU representation 400, according to various embodiments described herein. The simulated DPU representation represents the overall architecture of the DPU designed as part of performing the process 200, described above in connection with FIG. 2. The simulated DPU representation 400 includes an offchip memory block 401, an embedded CPU block 403, PCIe shim blocks 405 and 407, DMA blocks 409 and 411, a router block 413 and 417, a protocol block 415, and ethernet shim blocks 419 and 421. The PCIe shim blocks 405 and 407, DMA blocks 409 and 411, a router block 413 and 417, a protocol block 415, and ethernet shim blocks 419 and 421, are aspects of an FPGA chip of the DPU. The simulated representation of the DPU 400 illustrates the overall architecture of a DPU card.

The DPU creation system 100 arranges hardware modules, protocols, and interfaces (i.e., between protocols, hardware modules, or both), based on one or more form factors indicated by design specifications. For example, the AMD U45N card offers advanced features with an embedded CPU and two 100 Gbps Ethernet ports, but requires a larger PCIe Full-Height Half-Length (FHHL) form factor. As another example, the AMD U50 card offers fewer features but supports a compact PCIe Half-Height Half-Length (HHHL) form factor, making it suitable for space-constrained environments. Another example is the AMD V80 card, which doubles the bandwidth for PCIe and Ethernet but implements additional PCIe and Ethernet interfaces directly in the FPGA. In some embodiments, to generate a DPU design that takes into account the variations in different hardware platforms, the DPU creation system 100 includes one or more shims into the DPU design, such as the PCIe Shims 405 and 407 and Ethernet Shims 419 and 421; one or more routing mechanisms to handle communication between different destinations, such as the routers 417 and 413; other components; or some combination thereof. To handle the variation on the hardware platforms, MB-shell incorporates various PCIe and Ethernet Shims, as well as a routing mechanism to handle communication between different destinations. As a result, in such embodiments, the DPU creation system 100 is able to create DPU designs that support multiple hardware platforms and that can be integrated in different types of systems.

The offchip memory 401 is a computer memory component that is designated to be outside of the FPGA chip of the DPU. The embedded CPU 403 maintains compatibility with standard protocols by handling non-performance-critical control paths.

The FPGA chip includes the shims 405, 407, 419, 421, routers 413 and 417, DMAs 409 and 411, and protocols 415. In some embodiments, the DPU creation system 100 designs the FPGA chip to include one or more standardized interfaces, such as DMAs (e.g. an AXI-Stream based DMA interface to facilitate bulk data transfers to and from the host and embedded CPU) an AXI-MM interface to enable access to specific memory spaces (e.g., configuration registers), and an AXIS interface to handle sending and receiving data to and from the network. In some embodiments, the DPU creation system 100 includes one or more standardized interfaces in the FPGA chip based on the protocols selected for the DPU. By including these fixed interfaces, the DPU creation system 100 improves the functioning of the protocols included in the FPGA, including the composed protocols, by ensuring seamless integration and reducing development complexity.

FIG. 5 is a flow diagram of a sample DPU testing process 500, according to various embodiments described herein. In some embodiments, the process 500 is performed as part of performing the process 200, described above in connection with FIG. 2.

The process 500 begins, after a start block, at act 501, where the DPU creation system receives an indication of one or more protocols and one or more hardware modules for a simulated DPU. In some embodiments, the indication of one or more protocols and one or more hardware modules are selected for the simulated DPU as part of performing the process 200, described above in connection with FIG. 2.

The process 500 proceeds to act 503, where the DPU creation system selects one or more verification libraries based on the one or more modules and the one or more protocols. In some embodiments, the DPU creation system receives the one or more verification libraries from a library module, such as the library module 102. In some embodiments, the verification libraries include one or more verification protocols for one or more protocols stored in the library module. For example, the verification libraries may include verification protocols for NVMe, PCIe, AMBA, or other protocols. which provides a structured and reusable environment for verifying complex hardware designs. In some embodiments, at least a portion of the one or more verification libraries are libraries created as a result of testing other DPU designs by the DPU creation system.

The process 500 proceeds to act 505, where the DPU creation system applies the one or more verification libraries to the simulated DPU to obtain test data. In some embodiments, the DPU creation system uses one or more verification methodologies, such as the Universal Verification Methodology (UVM), to test the simulated DPU when applying the one or more verification libraries to the simulated DPU to obtain test data. In some embodiments, applying the verification libraries to the simulated DPU includes testing the DPU on the hardware and software levels. In some embodiments, at last one of the one or more verification libraries are received via input, such as user input, an indication of one or more verification libraries in design specifications for the DPU, etc. In some embodiments, the one or more verification libraries include an indication of one or more inputs to be triggered, one or more expected outputs, one or more protocols tested by the verification library, one or more hardware modules tested by the verification library, or some combination thereof.

In some embodiments, the DPU creation system performs act 505 multiple times with regards to one or more test cases indicated by the one or more verification libraries. In such embodiments, the DPU creation system may perform act 505 multiple times based on input indicating the number of times the simulated representation of the DPU is to be tested, such as via user input, an indication of the number of tests in design specifications, etc. In some embodiments, as part of performing act 505, the DPU creation system performs the process 600, described below in connection with FIG. 6.

The process 500 proceeds to act 507, where the DPU creation system identifies one or more testing outcomes from the test data. In some embodiments, the DPU creation system uses the test data, identified testing outcomes, or a combination thereof, to change aspects of the simulated representation of the DPU, such as when performing acts 209, 211, and 213, of the process 200 described above in connection with FIG. 2. In some embodiments, the one or more testing outcomes indicate data regarding one or more connections or interfaces whose timing can be enhanced; one or more timing violations; one or more wires; one or more registry values; one or more regions to be reconfigured; one or more regions to which a bug fix or upgraded version is to be applied; one or more parameters for tuning; other testing outcomes; or some combination thereof. In some embodiments, the DPU creation system generates one or more visualizations or summaries based on the one or more testing outcomes.

In some embodiments, the DPU creation system launches one or more Computer Aided Design (“CAD”) processes for one or more aspects of the simulated DPU based on the one or more testing outcomes. In such embodiments, the DPU creation system may select a CAD process and an aspect of the simulated DPU based on the one or more testing outcomes.

The process 500 proceeds to act 509, where the DPU creation system determines whether at least one testing outcome indicates one or more bugs or potential improvements to the DPU. If the at least one testing outcome indicates one or more bugs or potential improvements, the process 500 proceeds to act 511, otherwise, the process 500 ends.

At act 511, the DPU creation system identifies a fix or potential improvement for the one or more bugs or potential improvements. In some embodiments, the DPU creation system performs act 511 in a similar manner to act 213 of the process 200, described above in connection with FIG. 2.

The process 500 proceeds to act 513, where the DPU creation system stores an indication of the bug or potential improvement, at least one protocol associated with the bug or potential improvement, at least one module associated with the bug or potential improvement, and the fix or improvement associated with the bug or potential improvement. In some embodiments, the DPU creation system stores data related to the bug or potential improvement in a library module, such as the library module 102. In some embodiments, the DPU creation system uses the data related to the bug or potential improvement to create other DPUs, such as by identifying similar components in a DPU that experienced the bug or potential improvement and a new DPU that is being created. In such embodiments the DPU creation system may design the new DPU by using the data regarding the bug or potential improvement, such as by implementing a bug fix or potential improvement when initially designing the DPU.

After act 513, the process 500 ends.

FIG. 6 is a flow diagram of a sample process 600 to inject monitoring code into a simulated representation of a DPU, according to various embodiments described herein. In some embodiments, the process 600 is performed as part of performing the process 500, described above in connection with FIG. 5.

The process 600 begins, after a start block, at act 601, where the DPU creation system receives an indication of a module of a simulated DPU to be monitored. In some embodiments, the DPU creation system selects the module of the simulated DPU to be monitored based on test data. For example, the test data may indicate that the utilization of the module exceeded a threshold amount.

The process 600 proceeds to act 603, where the DPU creation system adds monitoring code to the simulated DPU based on the indicated module to be monitored. In some embodiments, the monitoring code monitors one or more aspects of the DPU design, such as first in first outs (“FIFOs”), interfaces, protocols, modules, wires, registries, etc. In some embodiments, the monitoring code collects statistics such as: a total number of entries written to and read from each FIFO; a peak occupancy of each FIFO during operation; the longest period when a FIFO maintained utilization that exceeds a threshold level; the cumulative time during which a FIFO experienced utilization that exceeds a threshold level; or other aspects of FIFOs, interfaces, protocols, modules, etc., that can be monitored. In some embodiments, the DPU creation system identifies one or more interfaces as active or inactive, identifies congestion areas, identifies starvation areas, identifies other characteristics of the flow of data through the DPU, identifies mismatches between components that produce data and components that consume data, identifies the occupancy of each FIFO, optimizes the size of FIFOs based on the occupancy of each FIFO, or some combination thereof, based on the monitored data.

The process 600 proceeds to act 605, where the DPU creation system tests the simulated DPU based on one or more verification libraries. In some embodiments, the DPU creation system tests the simulated DPU in a similar manner to performing act 505 of the process 500, described above in connection with FIG. 5.

The process 600 proceeds to act 607, where the DPU creation system receives monitored data associated with the module via the monitoring code. In some embodiments, the monitored data is transmitted to a “debugging hub” associated with the DPU creation system. The debugging hub may be a computer system that receives monitored data and makes the data available to the DPU creation system. In some embodiments, the DPU creation system receives monitored data from the debugging hub periodically.

After act 607, the process 600 ends.

Below are example embodiments of how the DPU creation system may be used to generate a DPU design.

The following two examples relate to designing a DPU for Network Acceleration. The rise of data-intensive workloads, such as AI, machine learning, and big data analytics, is driving a surge in network usage within modern data centers. Additionally, high-bandwidth applications and the shift toward distributed architectures, which require constant high-speed communication between disaggregated components, further amplify the demand for network resources. As a result, hardware-based network acceleration is becoming increasingly important, with a growing focus on extending this acceleration to support more complex services.

Network acceleration can be seen as the foundation for accelerating data center services. TCP/IP (Transmission Control Protocol/Internet Protocol) is the foundational networking suite that facilitates reliable, end-to-end data communication across diverse systems. Despite the availability of newer protocols, TCP/IP remains widely utilized in data center environments due to its compatibility and proven reliability. However, traditional Linux TCP/IP stacks were not designed to scale efficiently with increasing network I/O demands, leading to inefficiencies in handling small packets at high rates. This limitation has driven the need for TCP/IP acceleration across various services to address performance bottlenecks.

In this example, the DPU creation system generates a DPU design that uses the TOE protocol, which offloads the full TCP/IP stack from CPU to hardware, including connection establishment and teardown. Thus, the DPU bypasses the Linux TCP stack to reduce CPU usage and packets of any size are able to be processed it higher speeds than other DPUs.

RDMA (Remote Direct Memory Access) is used by modern data centers to enable low-latency, high-throughput communication by bypassing the kernel and CPU for data transfers. This capability reduces overhead and improves scalability, making it useful for latency-sensitive applications and large-scale distributed systems. RoCEv2 (RDMA over Converged Ethernet version 2) is the most widely adopted network protocol for enabling RDMA in modern datacenters due to its performance and compatibility with Ethernet. In RoCEv2, a Queue Pair (QP) serves as a virtual communication port, facilitating data exchange between endpoints. Each QP functions as an independent channel, managing communication tasks. As data centers expand, the ability to efficiently manage and scale a large number of QPs becomes increasingly important to maintain high performance and resource efficiency.

In this example the DPU creation system generates a DPU design that uses a modified RoCEv2 protocol that accelerates the RoCEv2 protocol to support extensive RDMA features and improve the scalability of the protocol. By using the modified RoCEv2 protocol, the designed DPU is able to handle more connections than other DPUs, and is thus able to handle more QPs than other DPUs.

The next example relates to storage virtualization. With the emergence of big data workloads with massive I/O processing, most cloud providers now provide high-performance block storage and also offer comprehensive big data analytics solutions to meet these needs. As a result, storage virtualization has become increasingly critical to support the scalability, flexibility, and performance required in these environments. However conventional approaches are limited in terms of scalability and efficiency.

To support the demand for high-performance virtual block storage, the DPU creation system may create a DPU with a composed protocol that includes: (1) the NVMe-frontend protocol that emulates an NVMe PCI interface from the host; (2) the NVMe-backend protocol that controls local-attached NVMe devices on the same PCIe switch; and (3) the P2P DMA to transfer data to local NVMe devices. The NVMe-frontend protocol also provides virtualization capability by supporting SR-IONT and PCI passthrough. By enabling the frontend protocol, the designed DPU represents itself as a standard NVMe PCI device that supports SR-IONT and passthrough even though the attached NVMe devices do not have any virtualization capability. By using a PDU with the composed protocol, the DPU is able to preserve all CPU resources associated with I/O processing, except for the minimal CPU usage required for event notification, thus freeing the CPU's resources to be used for other tasks.

The next two examples relate to storage disaggregation. In modern datacenters, storage disaggregation is becoming increasingly important due in order to flexibly and efficiently manage resources. By decoupling storage from compute resources, organizations can scale each component independently, optimizing utilization and reducing costs. This approach enhances system resilience and allows for seamless upgrades or replacements without disrupting operations. Effectively implementing storage disaggregation is crucial for maintaining high performance and adaptability in dynamic computing environments.

NVMe over Fabric (NVMe-oF) is a widely adopted solution for enabling storage disaggregation by allowing high-performance storage devices to connect over a network. It operates with two primary components: the initiator, which resides on the compute node and sends NVMe-oF commands over transport layer, and the target, which runs on the storage node and accessing physical storage based on these commands. It is a standardized protocol designed to operate seamlessly over fabric protocols, such as TCP or RoCEv2, which handle the underlying transport layer. However, NVMe-oF introduces a significant CPU resource overhead which can impact overall system efficiency. Despite its benefits, the CPU overhead highlights the need for further optimization.

In this example, the DPU creation system may generate a DPU design that includes a combination of protocols, such as the NVMe and TCP protocols. In such an example, the combined protocol may include the NVMe frontend protocol and an NVMe/TCP adaptor protocol. The NVMe frontend protocol allows the DPU to act as an NVMe PCI device and issue NVMe commands. The NVMe/TCP adaptor protocol includes the TOE protocol and operates on top of the TCP/IP transport layer. Thus, the DPU is able to be used as a NVMe PCI device that functions as if a local NVMe were installed. Additionally, if the DPU board includes an embedded CPU, software used by the combined protocol may be run on the embedded CPU instead of the CPU cores of the host server, which reduces the overall resource usage of the host server CPU.

In another example, the DPU creation system may generate a DPU design that includes a combination of the NVMe and RoCEv2 protocols. The combination of the protocols is similar to the combination of the NVMe and TCP protocols, except for the use of the RoCEv2 and NVMe/RoCE adaptor protocols. The DPU designed by the DPU creation system in this example may also include an embedded CPU to run software used by the combined protocol and conserve resource usage of the host server CPU.

The next two examples relate to an AI inference server. As network technologies continuously advance and achieve high data rates, conventional web servers (e.g., Ng-inx, Apache) encounter increasing bottlenecks in performance and CPU utilization because they usually rely on TCP-based protocols (e.g., HTTP, gRPC). However, conventional web servers do not need to be modified to utilize a DPU designed with the TOE protocol, which would resolve the bottlenecks. For example, the DPU creation system may generate a DPU design with the TOE protocol for use by an AI inference server to reduce latency and process more requests per second by offloading TCP packet processing tasks to the DPU.

Data preprocessing is a step in AI pipelines that ensures that incoming data is consistently formatted, denoised, and suitably scaled before it reaches the artificial intelligence model. However, these preprocessing tasks often have non-negligible overheads, especially for image-based AI tasks. The DPU creation system may generate a DPU design that utilizes a modified JPEG decoder protocol that maximizes the burst size of the output interface to off-chip memory, increases memory-write efficiency, and produces images in the format consumed by the AI system. The JPEG decoder protocol includes YUV to RGB color conversion of images and re-ordering the output from the JPEG-specific minimum coded unit format to the row-major format. By operating this way, the DPU does not consume CPU or GPU resources needed by the AI system.

An end-to-end AI inference server (e.g., Triton Inference Server) is a specialized platform designed to deploy and execute trained neural network (NN) models in high-throughput, low-latency environments. It typically includes: (1) a web server that receives inference requests and returns results over the network, (2) pre-and post-processing to prepare input data for consumption by NN models and finalize the output result to be returned, (3) computational components to process the data through one or more NN models, and (4) data transfer among NICs, CPUs, and AI accelerators usually over PCIe.

In this example, the DPU creation system may generate a DPU design that uses a TOE protocol to accelerate web serving, a pre-and post-processing protocol to accelerate pre-processing, and the P2P DMA protocol to directly transfer pre-processed input to a GPU directly. In such an example, when a web server receives TOE-accelerated inference requests, the preprocessing operations are offloaded to the DPU. Once the DPU performs data pre-processing and P2P data communication, the GPU calculates artificial intelligence computations without further data transfer.

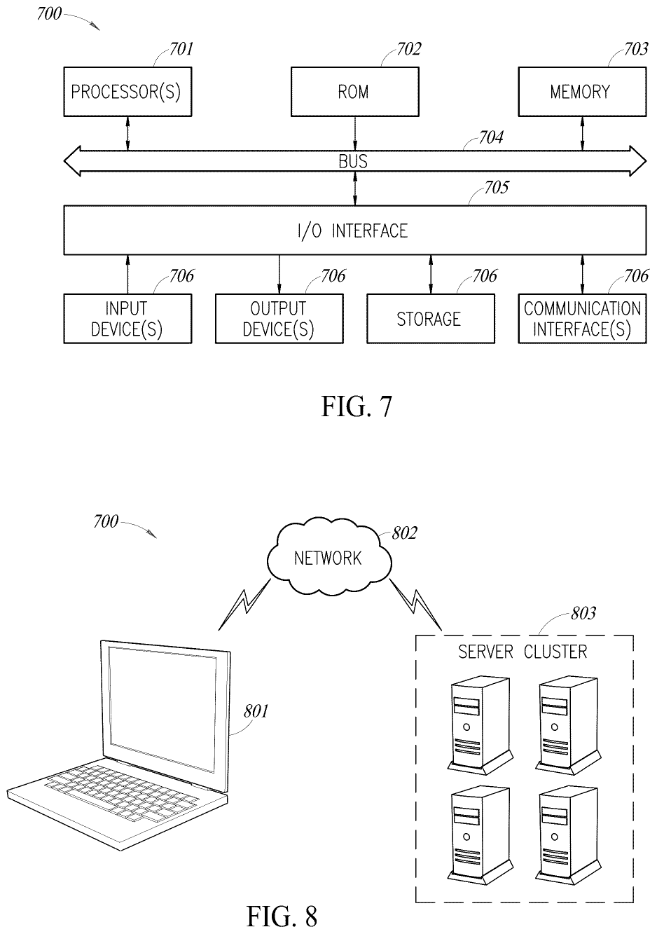

FIG. 7 is a schematic block diagram of an exemplary computing device 700 that can be used to implement embodiments of the present disclosure. The computing device 700 is intended to represent a wide variety of digital computing systems, which can be stationary or mobile. Examples include, but are not limited to, desktop computers, laptops, workstations, servers (including blade and mainframe servers), smartphones, tablet computers, personal digital assistants (PDAs), wearable devices (e.g., smartwatches, smart glasses), and Internet of Things (IoT) devices. The computing device 700 can also represent specialized or embedded platforms such as complex programmable logic devices (CPLDs), application-specific standard products (ASSPs), or systems integrated into industrial control equipment. The components shown, their connections, and their relationships are exemplary and are not intended to limit the scope of the disclosure.

As shown in FIG. 7, the computing device 700 includes one or more processors 701, memory 703, storage 708, and an I/O interface 705, all interconnected via a system bus or interconnect 704.

The processors 701 are responsible for processing instructions and may be a general-purpose processor, controller, microcontroller, or a specialized processor. Embodiments may be implemented in a digital electronic circuit system, an integrated circuit system, or combinations thereof. Non-limiting examples of processing circuitry include a central processing unit (CPU), a graphics processing unit (GPU), an application-specific integrated circuit (ASIC), an application-specific standard product (ASSP), a field-programmable gate array (FPGA), a complex programmable logic device (CPLD), or a specialized accelerator for artificial intelligence (AI) workloads, such as a tensor processing unit (TPU) or a neural processing unit (NPU). In many modern devices, multiple processing components may be integrated onto a single System-on-Chip (SoC).

The memory 703 stores information within the computing device 700. It is typically a volatile, random-access memory (RAM). The device may also include non-volatile read-only memory (ROM) 702 for storing firmware or basic boot instructions. The processor 701 can execute computer programs and instructions stored in memory 703, which may be loaded from the non-volatile storage 708 or received from a network via the communication interface 709.

The storage 708 provides for non-volatile, long-term storage of data and program instructions. As examples, the storage 708 may be a hard disk drive (HDD), a solid-state drive (SSD), a flash memory device, an optical disc, or any suitable combination thereof.

The I/O interface 705 couples the computing device 700 to a plurality of other components. These components include an input unit 706, which may include one or more input devices such as a keyboard, mouse, touchscreen, microphone, or biometric sensor, and an output unit 707, which may include one or more output devices such as a display (e.g., LCD or OLED screen), speakers, or a haptic feedback device. To support rich user interaction, the input unit 706 may also include pointing devices (e.g., trackballs, styluses) and multimodal sensors (e.g., depth cameras, gesture or voice recognition), while output unit 707 may further provide tactile or haptic feedback.

The I/O interface 705 also connects to a communication interface 709 for exchanging data with other devices over a network. The communication interface 709 may include one or more wired or wireless transceivers, such as Ethernet, Wi-Fi, Bluetooth, cellular (4G/5G/6G), ultra-wideband (UWB), or high-speed optical links, to enable low-latency, high-throughput data transfer across LANs, WANs, or the Internet.

The systems and methods described herein can be implemented as computer-executable instructions, such as a software program, stored on a non-transitory computer-readable medium and executed by the processor(s) 701. A non-transitory computer-readable medium may be a tangible medium that can contain or store a program for use by an instruction execution system. Examples include electronic, magnetic, optical, electromagnetic, or semiconductor systems, such as a RAM, a ROM, an EPROM, a flash memory, an SSD, a CD-ROM, or a hard disk.

The described technologies can be implemented in various computing environments. For example, they can be deployed in cloud computing environments, leveraging scalable, on-demand resources from a cloud provider (e.g., as Infrastructure-as-a-Service (IaaS) or Platform-as-a-Service (PaaS)). Alternatively, they may be deployed on edge computing nodes to perform computation closer to data sources, thereby reducing latency and bandwidth usage. Furthermore, hybrid environments that combine both cloud and on-premises or edge resources may be utilized.

To support flexible deployment and scalability, the system may utilize virtualization (e.g., virtual machines) and containerization technologies, often managed by an orchestration platform. For processing large datasets or complex AI models, the system can employ distributed and parallel computing frameworks to orchestrate workloads across multiple nodes in a cluster. The computing system may include back-end components (e.g., a data server), middleware components (e.g., an application server), and/or front-end components (e.g., a client computer with a graphical user interface or web browser through which a user can interact with an implementation of the disclosure). Program codes for implementing the methods of the present disclosure may be written in one or more programming languages or combinations thereof.

FIG. 8 illustrates an exemplary system architecture in which embodiments of the disclosure may be implemented. The architecture shows a distributed client-server model but is not intended to be limiting. For example, it can represent the previously described multi-tier architecture where the front-end, middleware, and back-end layers are themselves distributed or containerized. In other embodiments, the described methods may be performed entirely on a single standalone device or in different architectures.

The architecture includes one or more client devices 801, a server system 803, and a network 802 connecting them. The client device 801 serves as an endpoint for user interaction, such as a smartphone or desktop computer running a web browser or a dedicated application, and the server system 803 provides backend services, such as performing the methods for executing a task for a large language model or other tasks. The client device 801 and the server system 803 may each be any embodiment of the computing device 700 of FIG. 7, for example. Each node can dynamically scale its compute, memory, and accelerator resources via orchestration frameworks, and may expose APIs for secure multi-tenant access. The server system 803 may include a single server or a cluster of servers (831-834), which can be physical or virtualized machines in a data center or cloud environment, and may also be a distributed system or integrated with a blockchain, for example. The network 802 provides the communication link between the client device 801 and the server system 803 and can be any combination of a Local Area Network (LAN), a Wide Area Network (WAN), the Internet, or various wireless and wired connections. The network 802 may also provide east-west connectivity within the server cluster 803, supporting technologies such as software-defined networking (SDN) and zero-trust security models.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A system comprising:
at least one processor; and
at least one memory coupled to the at least one processor, the memory having computer-executable instructions stored thereon that, when executed by the at least one processor, cause the system to:
receive an indication of one or more data processing unit (DPU) design specifications;
select one or more protocols for a DPU based on the one or more DPU design specifications;
select one or more hardware modules for the DPU based on the one or more protocols;
generate a simulated representation of the DPU by composing the one or more protocols and the one or more hardware modules;
test the simulated representation of the DPU to obtain test result data;
determine whether to modify one or more aspects of the DPU based on the test result data and the one or more DPU design specifications;
based on a determination that one or more aspects of the DPU are to be modified, modify the one or more aspects of the simulated representation of the DPU; and
cause a hardware implementation of a DPU to be created based on the simulated representation of the DPU.

2. The system of claim 1, wherein, to generate the simulated representation of the DPU, the system is further caused to:
generate a graph of the one or more protocols and one or more interfaces between the protocols, the one or more interfaces being associated with the one or more hardware modules, wherein the one or more protocols are represented by nodes and the one or more interfaces are represented by edges.

3. The system of claim 1, wherein, to select the one or more protocols, the system is further caused to:
access data indicating a function of each protocol of a plurality of protocols;
access data indicating one or more data interactions of each protocol of the plurality of protocols with one or more other protocols of the plurality of protocols; and
select the one or more protocols based on the data indicating the function of each protocol of the plurality of protocols, the data indicating one or more data interactions of each protocol of the plurality of protocols with one or more other protocols of the plurality of protocols, and the DPU design specifications.

4. The system of claim 3, wherein, to select the one or more protocols, the system is further caused to:
combine at least two protocols based on a function of each of the at least two protocols and the DPU design specifications.

5. The system of claim 1, wherein, to select one or more hardware modules for the DPU, the system is further caused to:
identify a plurality of hardware modules based on the DPU design specifications;
access data indicating compatibility between each of the plurality of hardware modules and each of the one or more protocols; and
select the one or more hardware modules based on the compatibility of each of the plurality of hardware modules and each of the one or more protocols.

6. The system of claim 1, wherein, to generate a simulated representation of the DPU, the system is further caused to:
identify a resource cost for each hardware module of the one or more hardware modules;
identify a resource cost for each protocol of the one or more protocols; and
select a location within the DPU for each hardware module of the one or more hardware modules based on the resource cost for each hardware module and the resource cost for each protocol.

7. The system of claim 1, wherein, to test the simulated representation of the DPU, the system is further caused to:
access one or more pre-determined test cases for the one or more protocols and the one or more hardware modules; and
test the simulated representation of the DPU based on the one or more pre-determined test cases.

8. The system of claim 1, wherein, to test the simulated representation of the DPU, the system is further caused to:
identify one or more bugs encountered during the test of the simulated representation of the DPU, the one or more bugs affecting functionality of at least one protocol of the one or more protocols or functionality of at least one hardware module of the one or more hardware modules;
identify a solution for the one or more bugs encountered during the test of the simulated representation of the DPU; and
generate a test case for the at least one protocol or the at least one hardware module based on the one or more bugs and the solution.

9. The system of claim 1, wherein, to test the simulated representation of the DPU, the system is further caused to:
determine whether a resource utilization of at least one protocol of the one or more protocols or at least one hardware module of the one or more hardware modules has exceeded a threshold amount based on a first test of the simulated representation of the DPU;
select the at least one protocol or the at least one hardware module of the one or more hardware modules based on a determination that the resource utilization of the at least one protocol or the at least one hardware module exceeded the threshold amount;
implement monitoring code to the at least one protocol or the at least one hardware module in the simulated representation of the DPU, the monitoring code being configured to generate monitoring statistics during testing for the at least one protocol or the at least one hardware module;
perform a second test of the simulated representation of the DPU; and
receive monitoring statistics generated during the second test of the simulated representation of the DPU.

10. The system of claim 9, wherein, to determine whether a resource utilization of the at least one protocol or the at least one hardware modules has exceeded a threshold amount, the system is further caused to:
identify one or more bugs encountered during the test of the simulated representation of the DPU, the one or more bugs affecting functionality of at least one protocol of the one or more protocols or functionality of at least one hardware module of the one or more hardware modules.

11. The system of claim 9, wherein, to determine whether a resource utilization of the at least one protocol or the at least one hardware modules has exceeded a threshold amount, the system is further caused to:
identify one or more optimization directives included in the one or more DPU design specifications.

12. A method comprising:
receiving an indication of one or more data processing unit (DPU) design specifications;
selecting one or more protocols for a DPU based on the one or more DPU design specifications;
selecting one or more hardware modules for the DPU based on the one or more protocols;
generating a simulated representation of the DPU by composing the one or more protocols and the one or more hardware modules;
testing the simulated representation of the DPU to obtain test result data;
determining whether to modify one or more aspects of the DPU based on the test result data and the one or more DPU design specifications;
based on a determination that one or more aspects of the DPU are to be modified, modifying the one or more aspects of the simulated representation of the DPU; and
causing a hardware implementation of a DPU to be created based on the simulated representation of the DPU.

13. The method of claim 12, wherein generating the simulated representation of the DPU further comprises:
generating a graph of the one or more protocols and one or more interfaces between the protocols, the one or more interfaces being associated with the one or more hardware modules, wherein the one or more protocols are represented by nodes and the one or more interfaces are represented by edges.

14. The method of claim 12, wherein selecting the one or more protocols further comprises
access data indicating a function of each protocol of a plurality of protocols;
access data indicating one or more data interactions of each protocol of the plurality of protocols with one or more other protocols of the plurality of protocols; and
select the one or more protocols based on the data indicating the function of each protocol of the plurality of protocols, the data indicating one or more data interactions of each protocol of the plurality of protocols with one or more other protocols of the plurality of protocols, and the DPU design specifications.

15. One or more instances of non-transitory computer-readable media including processor-executable instructions configured to cause a processor to perform a method comprising:
receiving an indication of one or more data processing unit (DPU) design specifications;
selecting one or more protocols for a DPU based on the one or more DPU design specifications;
selecting one or more hardware modules for the DPU based on the one or more protocols;
generating a simulated representation of the DPU based on the one or more protocols and the one or more hardware modules;
testing the simulated representation of the DPU to obtain test result data;
determining whether to modify one or more aspects of the DPU based on the test result data and the one or more DPU design specifications;
based on a determination that one or more aspects of the DPU are to be modified, modifying the one or more aspects of the simulated representation of the DPU; and
causing a hardware implementation of a DPU to be created based on the simulated representation of the DPU.

16. The one or more instances of non-transitory computer-readable media of claim 15, wherein selecting one or more hardware modules for the DPU comprises:
identifying a plurality of hardware modules based on the DPU design specifications;
accessing data indicating compatibility between each of the plurality of hardware modules and each of the one or more protocols; and
selecting the one or more hardware modules based on the compatibility of each of the plurality of hardware modules and each of the one or more protocols.

17. The one or more instances of non-transitory computer-readable media of claim 15, wherein generating a simulated representation of the DPU comprises:
identifying a resource cost for each hardware module of the one or more hardware modules;
identifying a resource cost for each protocol of the one or more protocols; and
selecting a location within the DPU for each hardware module of the one or more hardware modules based on the resource cost for each hardware module and the resource cost for each protocol.

18. The one or more instances of non-transitory computer-readable media of claim 15, wherein testing the simulated representation of the DPU comprises:
accessing one or more pre-determined test cases for the one or more protocols and the one or more hardware modules; and
testing the simulated representation of the DPU based on the one or more pre-determined test cases.

19. The one or more instances of non-transitory computer-readable media of claim 15, wherein testing the simulated representation of the DPU comprises:
identifying one or more bugs encountered during the test of the simulated representation of the DPU, the one or more bugs affecting functionality of at least one protocol of the one or more protocols or functionality of at least one hardware module of the one or more hardware modules;
identifying a solution for the one or more bugs encountered during the test of the simulated representation of the DPU; and
generating a test case for the at least one protocol or the at least one hardware module based on the one or more bugs and the solution.

20. The one or more instances of non-transitory computer-readable media of claim 15, wherein testing the simulated representation of the DPU comprises:
determining whether a resource utilization of at least one protocol of the one or more protocols or at least one hardware module of the one or more hardware modules has exceeded a threshold amount based on a first test of the simulated representation of the DPU;
selecting the at least one protocol or the at least one hardware module of the one or more hardware modules based on a determination that the resource utilization of the at least one protocol or the at least one hardware module exceeded the threshold amount;
implementing monitoring code to the at least one protocol or the at least one hardware module in the simulated representation of the DPU, the monitoring code being configured to generate monitoring statistics during testing for the at least one protocol or the at least one hardware module;
performing a second test of the simulated representation of the DPU; and
receiving monitoring statistics generated during the second test of the simulated representation of the DPU.
